(19) United States
(12) Patent Application Publication
(10) Pub. No.: US 2007/0263366 A1
(43) Pub. Date: Nov. 15, 2007

(54) MULTIPURPOSE INPUT PLUG ASSEMBLY AND POWER ADAPTER HAVING THE SAME

(75) Inventors: Wen-Ching Wu, Taoyuan Hsien (TW); Chia-Liang Hsiao, Taoyuan Hsien (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: Delta Electronics, Inc., Taoyuan Hsien (TW)

(21) Appl. No.: 11/615,729

(22) Filed: Dec. 22, 2006

(30) Foreign Application Priority Data
May 11, 2006 (TW) 095116781

(51) Int. Cl. H05K 5/00

(52) U.S. Cl. 361/752

(57) ABSTRACT

A power adapter includes a housing, an output socket and a multipurpose input plug assembly. The housing contains a circuit board therein. The output plug has an end electrically connected to the circuit board. The multipurpose input plug assembly includes a first connector, a cable, a second connector, a first input plug and a second input plug. An end of the first connector is electrically connected to the circuit board. The cable is interconnected between the first connector and the second connector. The second connector is selectively coupled to the first input plug or the second input plug. When the first input plug is coupled with the second connector, a first input voltage is received by the first input plug. When the second input plug is coupled with the second connector, a second input voltage is received by the second input plug.

### FIELD OF THE INVENTION

The present invention relates to an input plug assembly, and more particularly to a multipurpose input plug assembly. The present invention also relates to a power adapter having such a multipurpose input plug assembly.

### BACKGROUND OF THE INVENTION

Recently, the general trends in designing portable electronic devices are toward small size, light weightiness and easy portability. The portable electronic devices such as mobile phones, personal digital assistants (PDAs), digital still cameras, digital video cameras, notebook computers and the like have built-in batteries. If no external power supply apparatus is provided to power the portable electronic device, the built-in battery is usually employed as the main power source. If the power supplied from the battery is insufficient, the user may simply plug an AC-to-DC power adapter into an AC wall outlet commonly found in most homes or offices so as to receive an AC voltage. The AC voltage is then converted into a DC power to be used for the portable electronic device and/or charge the built-in battery. Similarly, when the user is in an automobile or airplane, since only DC input power is available, the user can plug a DC-to-DC power adapter into a standard automobile lighter socket or a standard airplane power socket. By means of the DC-to-DC adapter, a regulated DC output voltage is provided for powering the portable electronic device.

Although these two power adapters can provide direct power and recharging capabilities, there are still some drawbacks. For example, the users need to carry two separate adapters to provide power to each portable electronic device. Since the users are forced to carry more than one power adapter, the volume and the overall weight of the baggage required to be carried are increased. For solving the above problems, a dual input AC/DC power adapter is developed. The dual input AC/DC power adapter has an AC-to-DC converter and a DC-to-DC converter, which are housed in a housing. By using this dual input AC/DC power adapter, the portable electronic device can receive either AC voltage or DC voltage. For example, when the user is in homes or offices, the dual input AC/DC power adapter can be plugged into an AC wall outlet to receive an AC voltage. Whereas, when the user is in an automobile or airplane, since only DC input power is available, the dual input AC/DC power adapter can be plugged into a standard automobile lighter socket or a standard airplane power socket to receive a DC voltage. By the circuitry of the dual input AC/DC power adapter, the received AC voltage or DC voltage can be converted into a regulated DC output voltage for powering the portable electronic device.

The operation principles and the circuitry configurations of the AC-to-DC power adapter, the DC-to-DC power adapter and the dual input AC/DC power adapter are known in the art, and are not redundantly described herein.

Referring to FIG. 1, a schematic outward view of a DC-to-DC power adapter is illustrated. The DC-to-DC power adapter 1 comprises a housing 10, an input socket 11, an output socket 12, a circuit board (not shown) housed in the housing 10, a first input plug assembly 13 and a second input plug assembly 14. The operation principles of the circuit board are known in the art, and are not redundantly described herein. The first input plug assembly 13 includes a first connector 131, a first cable 132 and a first plug 133 such as an automobile input plug. The second input plug assembly 14 includes a second connector 141, a second cable 142 and a second plug 143 such as an airplane input plug.

When the DC-to-DC power adapter 1 is used in an automobile, the first connector 131 of the first input plug assembly 13 is firstly coupled to the input socket 11 and then the first plug 133 is plugged into a standard automobile lighter socket (not shown). By the circuit board, the DC voltage received from the automobile can be converted into a regulated DC output voltage for powering the portable electronic device. Similarly, when the DC-to-DC power adapter 1 is used in an airplane, the second connector 141 of the second input plug assembly 14 is firstly coupled to the input socket 11 and then the second plug 143 is plugged into a standard airplane socket (not shown). By the circuit board, the DC voltage received from the airplane can be converted into a regulated DC output voltage for powering the portable electronic device.

The DC-to-DC power adapter 1 can be used in either the automobile or the airplane. However, in order to be used in the automobile and the airplane, the input plug assembly 13 and the second input plug assembly 14 should be carried at a time. For portability and convenience, it is necessary to reduce the overall volume and/or weight of the input plug assembly 13 and the second input plug assembly 14.

Likewise, the overall volume and/or weight of the input plug assembly 13 and the second input plug assembly 14 used in the dual input AC/DC power adapter (not shown) also need to be reduced.

In views of the above-described disadvantages resulted from the conventional method, the applicant keeps on carving unflaggingly to develop a multipurpose input plug assembly according to the present invention through wholehearted experience and research.

### SUMMARY OF THE INVENTION

It is an object of the present invention to provide a multipurpose input plug assembly used in a power adapter, in which the multipurpose input plug assembly can be used in many instances and is advantageous of having reduced overall volume and weight.

Another object of the present invention is to provide a power adapter having such a multipurpose input plug assembly.

In accordance with an aspect of the present invention, there is provided a power adapter. The power adapter comprises a housing, an output plug and a multipurpose input plug assembly. The housing contains a circuit board therein. The output plug has an end electrically connected to the circuit board. The multipurpose input plug assembly includes a first connector, a cable, a second connector, a first input plug and a second input plug. An end of the first connector is electrically connected to the circuit board. The cable is interconnected between the first connector and the second connector. The second connector is selectively coupled to the first input plug or the second input plug. When the first input plug is coupled with the second connector, a first input voltage is received by the first input plug. When the second input plug is coupled with the second connector, a second input voltage is received by the second input plug.

In an embodiment, the first input plug is an automobile plug to be plugged into an automobile lighter socket, and the second input plug is an airplane plug to be plugged into an airplane power socket.

In an embodiment, the first connector comprises a first insulating member and a first terminal. The first terminal has an end electrically connected to the circuit board and the other end covered by the first insulating member.

In an embodiment, the second connector comprises a second insulating member, a second terminal, an insulating ring and a receiving portion. The second terminal has an end covered by the second insulating member. The insulating ring is formed at the interface between the second insulating member and the second terminal uncovered by the second insulating member. The receiving portion is defined between the second insulating member and the insulating ring.

In an embodiment, at least a portion of the insulating ring has an indentation, and the first and second input plug have individual first and second fastening members corresponding to the indentation of the insulating ring.

In an embodiment, the first input plug is engaged with the second connector by moving a rear end of the first input plug toward the second connector such that the first fastening member is received in the receiving portion through the indentation of the insulating ring, and then rotating the first input plug such that the first fastening member is sustained against the inner wall of the insulating ring.

In an embodiment, the first input plug further comprises a third terminal, and when the first input plug is engaged with the second connector, the third terminal is in contact with the second terminal of the second connector.

In an embodiment, the second input plug is engaged with the second connector by moving a rear end of the second input plug toward the second connector such that the second fastening member is received in the receiving portion through the indentation of the insulating ring, and then rotating the second input plug such that the second fastening member is sustained against the inner wall of the insulating ring.

In an embodiment, the second input plug further comprises a fourth terminal, and when the second input plug is engaged with the second connector, the fourth terminal is in contact with the second terminal of the second connector.

In an embodiment, the power converter is a DC-to-DC power adapter or a dual input AC/DC power adapter.

In accordance with another aspect of the present invention, there is provided a multipurpose input plug assembly for receiving one of a first input voltage and a second input voltage to be transmitted to a power adapter. The multipurpose input plug assembly comprises a first connector, a second connector, a cable and a first input plug and a second input plug. The first connector is electrically connected to the power adapter. The cable is interconnected between the first connector and the second connector. When the first input plug is coupled with the second connector, a first input voltage is received by the first input plug. When the second input plug is coupled with the second connector, a second input voltage is received by the second input plug.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic outward view of a DC-to-DC power adapter according to prior art;

FIG. 2 is a schematic outward view of a DC-to-DC power adapter according to a preferred embodiment of the present invention;

FIG. 3 schematically illustrates an embodiment of using the DC-to-DC power adapter in an automobile;

FIG. 4 is a partially enlarged cross-sectional view illustrating the connection between the first plug and the second connector of FIG. 3;

FIG. 5 schematically illustrates an embodiment of using the DC-to-DC power adapter in an airplane; and

FIG. 6 is a partially enlarged cross-sectional view illustrating the connection between the second plug and the second connector of FIG. 5.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

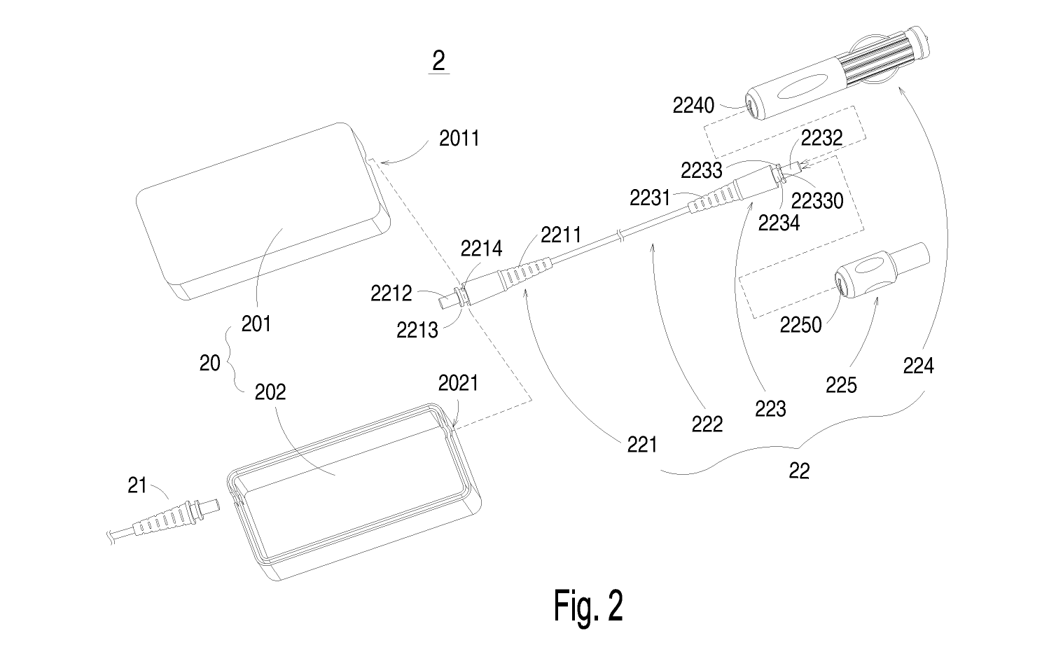

Referring to FIG. 2, a schematic outward view of a DC-to-DC power adapter according to a preferred embodiment of the present invention is illustrated. The DC-to-DC power adapter 2 comprises a housing 20, an output plug 21, a circuit board (not shown) housed in the housing 20 and a multipurpose input plug assembly 22. The housing 20 includes an upper cover 201 and a lower cover 202 engaged with each other. The multipurpose input plug assembly 22 includes a first connector 221, a cable 222, a second connector 223, a first input plug 224 and a second input plug 225. Examples of the first input plug 224 and the second input plug 225 include but are not limited to a standard automobile lighter plug and a standard airplane power plug, respectively.

The first connector 221 has an insulating member 2211 and a first terminal 2212. An end of the first terminal 2212 is electrically connected to the circuit board, and the other end of the first terminal 2212 is covered by the insulating member 2211. An insulating ring 2213 is formed at the interface between the insulating member 2211 and the first terminal 2212 uncovered by the insulating member 2211, so that a receiving portion 2214 is defined between the insulating member 2211 and the insulating ring 2213. The upper cover 201 and the lower cover 202 of the housing 20 have a first notch 2011 and a second notch 2021 corresponding to the receiving portion 2214 of the first connector 221. When the upper cover 201 and the lower cover 202, the first notch 2011 and a second notch 2021 are sheathed around the receiving portion 2214, so that the first connector 221 is firmly fixed onto the housing 20.

The second connector 223 has an insulating member 2231 and a second terminal 2232. An end of the second terminal 2232 is electrically connected to the cable 222, and the other end of the second terminal 2232 is exposed. An insulating ring 2233 is formed at the interface between the insulating member 2231 and the second terminal 2232 uncovered by the insulating member 2231, so that a receiving portion 2234 is defined between the insulating member 2231 and the insulating ring 2233. Especially, at least a portion of the insulating ring 2233 has an indentation 22330. Corresponding to the indentation 22330, the rear ends of the first input plug 224 and the second input plug 225 have individual fastening members 2240 and 2250, respectively.

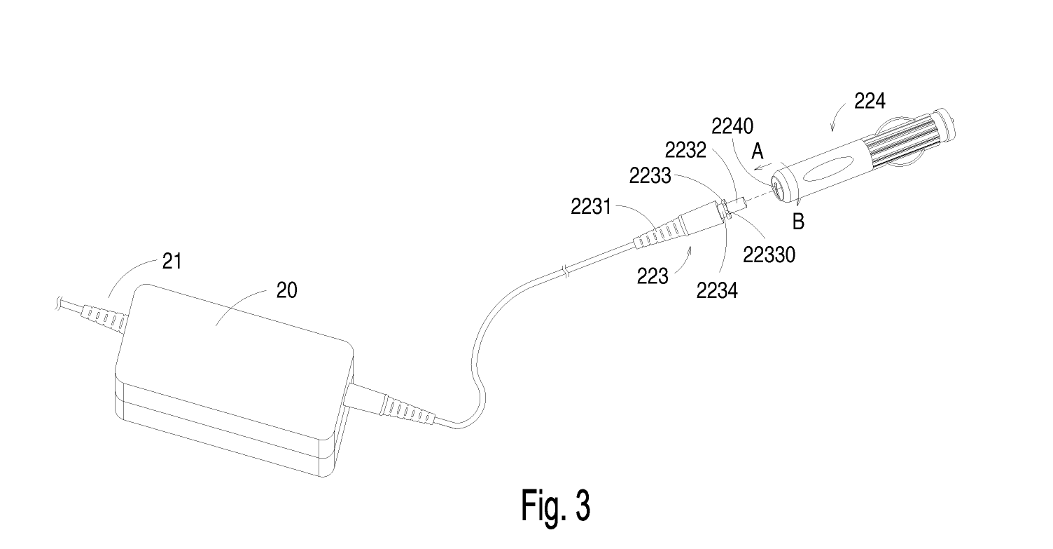

Please refer to FIG. 3, which schematically illustrates an embodiment of using the DC-to-DC power adapter 2 in an automobile. First of all, the first input plug 224 (i.e. an automatic input plug) should be moved in the direction A such that the fastening member 2240 is received in the receiving portion 2234 through the indentation 22330 of the insulating ring 2233 of the second connector 223. Subsequently, the first input plug 224 is rotated in the direction B such that the fastening member 2240 is sustained against the inner wall of the insulating ring 2233. Under this circumstance, the first input plug 224 is engaged with the second connector 223.

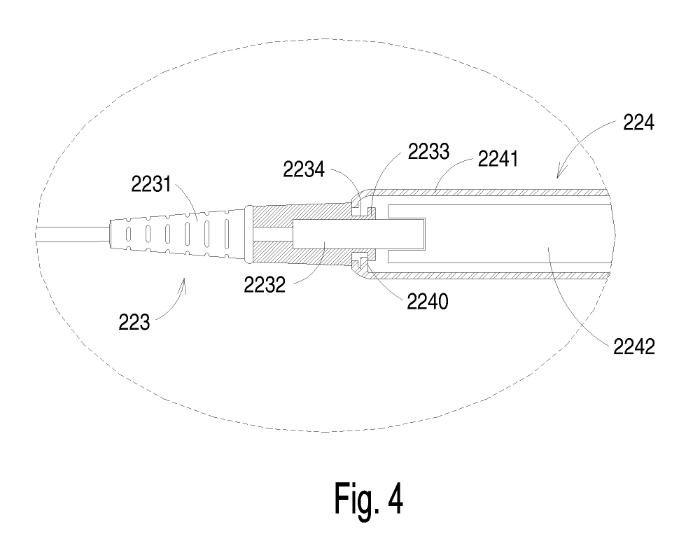

Please refer to FIG. 4, which is a partially enlarged cross-sectional view illustrating the connection between the first input plug 224 and the second connector 223. As shown in FIG. 4, in addition to the fastening member 2240, the first input plug 224 further includes an insulating member 2241 and a third terminal 2242. When the first input plug 224 is engaged with the second connector 223, the third terminal 2242 of the first input plug 224 is in contact with the second terminal 2232 of the second connector 223. If the first input plug 224 is inserted to a standard automobile lighter socket (not shown), the automobile DC voltage will be transmitted to the circuit board of the DC-to-DC power adapter 2 through the third terminal 2242 of the first input plug 224, the second terminal 2232 of the second connector 223, the cable 222 and the first terminal 2212 of the first connector 221. By the circuit board, the automobile DC voltage is converted into a regulated DC output voltage for powering the portable electronic device.

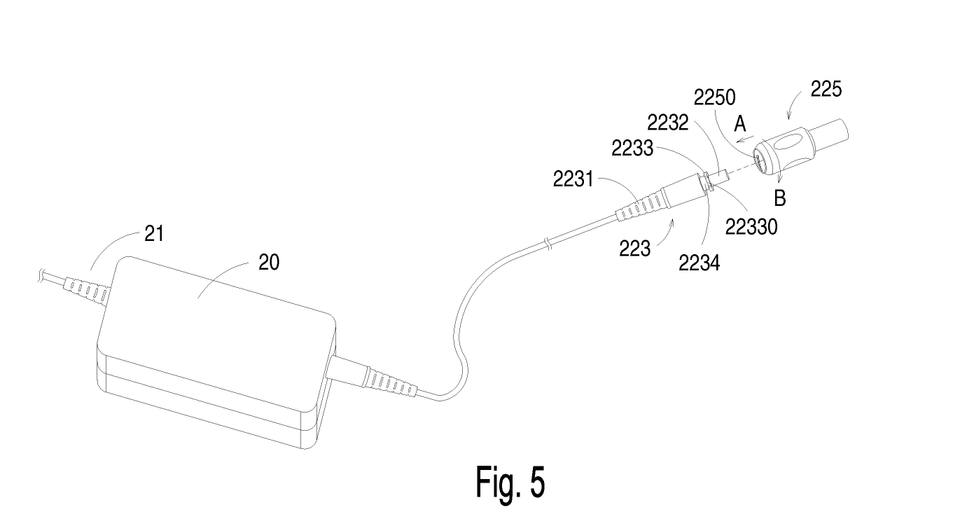

Please refer to FIG. 5, which schematically illustrates an embodiment of using the DC-to-DC power adapter 2 in an airplane. First of all, the second input plug 225 (i.e. an airplane input plug) should be moved in the direction A such that the fastening member 2250 is received in the receiving portion 2234 through the indentation 22330 of the insulating ring 2233 of the second connector 223. Subsequently, the second input plug 225 is rotated in the direction B such that the fastening member 2250 is sustained against the inner wall of the insulating ring 2233. Under this circumstance, the second input plug 225 is engaged with the second connector 223.

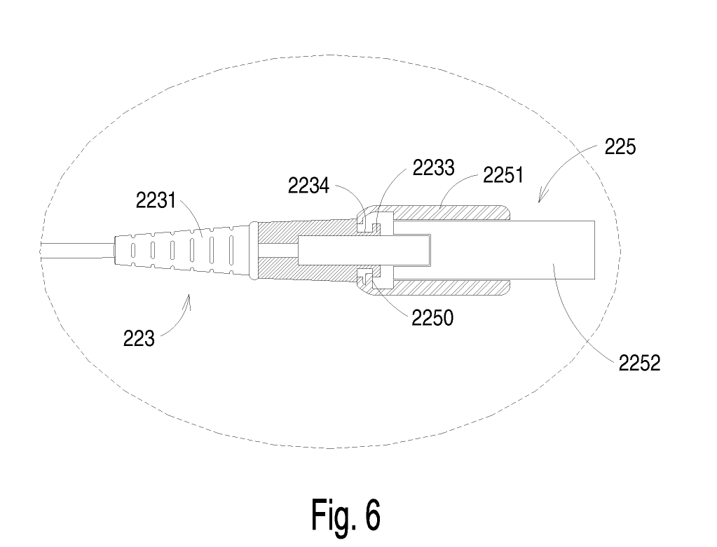

Please refer to FIG. 6, which is a partially enlarged cross-sectional view illustrating the connection between the second input plug 225 and the second connector 223. As shown in FIG. 6, in addition to the fastening member 2250, the second input plug 225 further includes an insulating member 2251 and a fourth terminal 2252. When the second input plug 225 is engaged with the second connector 223, the fourth terminal 2252 of the second input plug 225 is in contact with the second terminal 2232 of the second connector 223. If the second input plug 225 is inserted to a standard airplane power socket (not shown), the airplane DC voltage will be transmitted to the circuit board of the DC-to-DC power adapter 2 through the fourth terminal 2252 of the second input plug 225, the second terminal 2232 of the second connector 223, the cable 222 and the first terminal 2212 of the first connector 221. By the circuit board, the airplane DC voltage is converted into a regulated DC output voltage for powering the portable electronic device.

As previously described, since the conventional power adapter 1 needs two input plug assemblies 13 and 14 to be used in the automobile and the airplane, two connectors and two cables are required. In comparison with the prior art, the power adapter of the present invention needs only one cable 222 and two input plugs 224 and 225 to be used in the automobile and the airplane. As a consequence, the multipurpose input plug assembly of the present invention has reduced overall volume and/or weight of and is suitable for portability and storage.

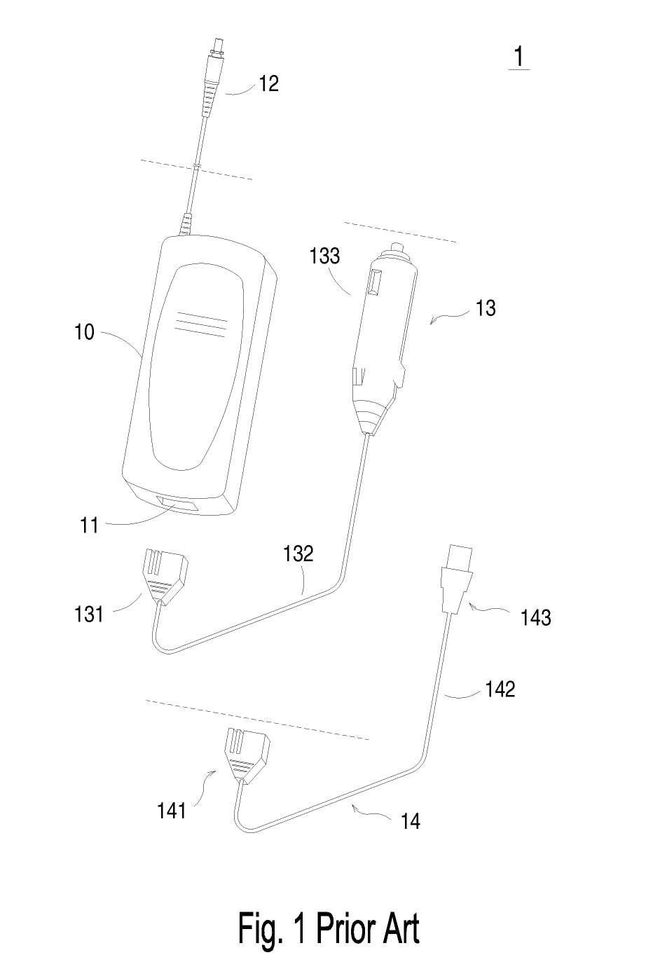

The embodiments of the present invention are illustrated by referring to a DC-to-DC power adapter. Nevertheless, the present invention can be applied to the dual input AC/DC power adapter. It is noted that, however, those skilled in the art will readily observe that numerous modifications and alterations of the first input plug 221 may be made while retaining the teachings of the invention. For example, the first input plug 221 can be replaced by the connector 131 as shown in FIG. 1, and the housing 20 has an additional input socket identical to the input socket as shown in FIG. 1. Under this circumstance, the first connector 221 of the multipurpose input plug assembly 22 of the present invention is detachably coupled to the housing 20. Accordingly, the above disclosure should be limited only by the bounds of the following claims.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power adapter comprising:
a housing containing a circuit board therein;
an output plug having an end electrically connected to said circuit board; and
a multipurpose input plug assembly including a first connector, a cable, a second connector, a first input plug and a second input plug, an end of said first connector being electrically connected to said circuit board, said cable being interconnected between said first connector and said second connector, said second connector being selectively coupled to one of said first input plug and said second input plug, wherein a first input voltage is received by said first input plug when said first input plug is coupled with said second connector, and a second input voltage is received by said second input plug when said second input plug is coupled with said second connector.

2. The power adapter according to claim 1 wherein said first input plug is an automobile plug to be plugged into an automobile lighter socket, and said second input plug is an airplane plug to be plugged into an airplane power socket.

3. The power adapter according to claim 1 wherein said first connector comprises:
a first insulating member; and
a first terminal having an end electrically connected to said circuit board and the other end covered by said first insulating member.

4. The power adapter according to claim 1 wherein said second connector comprises:
a second insulating member;
a second terminal having an end covered by said second insulating member;
an insulating ring formed at the interface between said second insulating member and said second terminal uncovered by said second insulating member; and
a receiving portion defined between said second insulating member and said insulating ring.

5. The power adapter according to claim 4 wherein at least a portion of said insulating ring of said second connector has an indentation, and said first and second input plug have individual first and second fastening members corresponding to said indentation of said insulating ring.

6. The power adapter according to claim 5 wherein said first input plug is engaged with said second connector by moving a rear end of said first input plug toward said second connector such that said first fastening member is received in said receiving portion through said indentation of said insulating ring, and then rotating said first input plug such that said first fastening member is sustained against the inner wall of said insulating ring.

7. The power adapter according to claim 6 wherein said first input plug further comprises a third terminal, and when said first input plug is engaged with said second connector, said third terminal is in contact with said second terminal of said second connector.

8. The power adapter according to claim 5 wherein said second input plug is engaged with said second connector by moving a rear end of said second input plug toward said second connector such that said second fastening member is received in said receiving portion through said indentation of said insulating ring, and then rotating said second input plug such that said second fastening member is sustained against the inner wall of said insulating ring.

9. The power adapter according to claim 8 wherein said second input plug further comprises a fourth terminal, and when said second input plug is engaged with said second connector, said fourth terminal is in contact with said second terminal of said second connector.

10. The power adapter according to claim 1 wherein said power converter is one of a DC-to-DC power adapter and a dual input AC/DC power adapter.

11. A multipurpose input plug assembly for receiving one of a first input voltage and a second input voltage to be transmitted to a power adapter, said multipurpose input plug assembly comprising:
a first connector electrically connected to said power adapter;
a second connector;
a cable interconnected between said first connector and said second connector; and
a first input plug and a second input plug, wherein a first input voltage is received by said first input plug when said first input plug is coupled with said second connector, and a second input voltage is received by said second input plug when said second input plug is coupled with said second connector.

12. The multipurpose input plug assembly according to claim 11 wherein said first input plug is an automobile plug to be plugged into an automobile lighter socket, and said second input plug is an airplane plug to be plugged into an airplane power socket.

13. The multipurpose input plug assembly according to claim 11 wherein said first connector comprises:
a first insulating member; and
a first terminal having an end electrically connected to a circuit board of said power adapter and the other end covered by said first insulating member.

14. The multipurpose input plug assembly according to claim 11 wherein said second connector comprises:
a second insulating member;
a second terminal having an end covered by said second insulating member;
an insulating ring formed at the interface between said second insulating member and said second terminal uncovered by said second insulating member; and
a receiving portion defined between said second insulating member and said insulating ring.

15. The multipurpose input plug assembly according to claim 14 wherein at least a portion of said insulating ring has an indentation, and said first and second input plug have individual first and second fastening members corresponding to said indentation of said insulating ring.

16. The multipurpose input plug assembly according to claim 15 wherein said first input plug is engaged with said second connector by moving a rear end of said first input plug toward said second connector such that said first fastening member is received in said receiving portion through said indentation of said insulating ring, and then rotating said first input plug such that said first fastening member is sustained against the inner wall of said insulating ring.

17. The multipurpose input plug assembly according to claim 16 wherein said first input plug further comprises a third terminal, and when said first input plug is engaged with said second connector, said third terminal is in contact with said second terminal of said second connector.

18. The multipurpose input plug assembly according to claim 15 wherein said second input plug is engaged with said second connector by moving a rear end of said second input plug toward said second connector such that said second fastening member is received in said receiving portion through said indentation of said insulating ring, and then rotating said second input plug such that said second fastening member is sustained against the inner wall of said insulating ring.

19. The multipurpose input plug assembly according to claim 18 wherein said second input plug further comprises a fourth terminal, and when said second input plug is engaged with said second connector, said fourth terminal is in contact with said second terminal of said second connector.

20. The multipurpose input plug assembly according to claim 11 wherein said power converter is one of a DC-to-DC power adapter and a dual input AC/DC power adapter.
